(19) United States
(12) Patent Application Publication
(10) Pub. No.: US 2007/0105368 A1
(43) Pub. Date: May 10, 2007

(54) Method of fabricating a microelectronic device using electron beam treatment to induce stress

(75) Inventors: Ting Y. Tsui, Garland, TX (US); Andrew McKerrow, Dallas, TX (US); Haowen Bu, Plano, TX (US); Robert Kraft, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/268,036

(22) Filed: Nov. 7, 2005

(51) Int. Cl. H01L 21/469

(52) U.S. Cl. 438/624; 438/778; 438/786; 438/791

(57) ABSTRACT

The present invention, in one embodiment, provides a method of fabricating a microelectronics device 200. This embodiment comprises forming a liner 310 over a substrate 210 and a gate structure 230, subjecting the liner 310 to an electron beam 405 and depositing a pre-metal dielectric layer 415 over the liner 310.

### TECHNICAL FIELD OF THE INVENTION

The present invention is directed in general to a method for manufacturing a microelectronics device, and more specifically, to a method of inducing stress into a channel region of a microelectronics device.

### BACKGROUND

There exists a continuing need to improve semiconductor device performance and further scale microelectronic devices. One characteristic that limits scalability and device performance is electron and hole mobility, also referred to as channel mobility, throughout the channel region of transistors. As devices continue to shrink in size, the channel region for transistors continues to also shrink in size, which can limit channel mobility.

One technique that may improve scaling limits and device performance is to introduce strain into the channel region, which can improve electron and hole mobility. Different types of strain, including expansive strain, tensile strain, and compressive strain, have been introduced into channel regions of various types of transistors in order to determine their affect on electron and/or hole mobility. Often, stress is introduced into the channel region by depositing a silicon nitride stress-inducing liner over the gate structures of the transistors. This liner is used to induce stress into the channel region of the transistor, and under preferred circumstances higher deposition temperatures are desirable to incorporate the desired amount of stress into the channel region. However, due to advances in technologies, the benefits obtained from the use of such liners as begun to encounter process limitations.

As device sizes have shrunk and performance requirements have increased, the industry has also sought ways in which to combat depletion within the reduced gate structures. To address this issue, the industry has found that it is highly advantageous to incorporate metal into polysilicon gates to form silicided gates. Because of the presence of the metal within the polysilicon gates, silicided gates suffer substantially less depletion effects and thereby meet the higher performance requirements of today's microelectronic devices. As such, silicided gates and fully silicided gates have gained in popularity.

Unfortunately, however, the amount of stress that can be incorporated into devices that include silicided gate structures by using the silicon nitride liner is limited due to thermal budgets. Typically, the amount of stress formed in the channel can be increased by increasing the deposition temperatures of the silicon nitride liner. However, these more desirable, higher temperatures, unfortunately, can lead to nickel piping defects within the silicided gate structures, which, in turn decreases transistor performance. Thus, when using silicon nitride materials as the liner, the maximum amount of stress cannot be incorporated into the channel region due to the required lower thermal budgets that are necessary to avoid nickel piping defects.

Accordingly, what is needed in the art is a process that avoids the deficiencies of the conventional processes discussed above.

### SUMMARY OF INVENTION

To overcome the deficiencies in the prior art, the present invention, in one embodiment, provides a method of fabricating a microelectronics device. This embodiment comprises forming a liner over a substrate and a gate structure, subjecting the liner to an electron beam, and depositing a pre-metal dielectric layer over the liner.

Another embodiment provides a method of fabricating an integrated circuit. This method comprises forming transistors that comprise gate electrodes over a microelectronics substrate, forming a liner over the microelectronics substrate and the gate electrodes, subjecting the liner to an electron beam, depositing a pre-metal dielectric layer over the liner, forming interlevel dielectric layers over the pre-metal dielectric layer, and forming interconnects in the pre-metal and interlevel dielectric layers to electrically connect the transistors to form an operative integrated circuit.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a partial sectional view of one embodiment of a microelectronics device, as provided by the present invention;

FIG. 2 illustrates a sectional view of a partially completed microelectronics device manufactured in accordance with the principles of the present invention and as discussed with respect to FIG. 1;

FIG. 3 illustrates a sectional view of the partially completed microelectronics device illustrated in FIG. 2 after the conventional deposition of a liner;

FIG. 4A illustrates a sectional view of the partially completed microelectronics device illustrated in FIG. 3 during subjecting the liner to an electron beam;

FIG. 4B illustrates a sectional view of the partially completed microelectronics device illustrated in FIG. 4A following the deposition of the pre-metal dielectric layer;

FIG. 5 is a graph illustrating the amount of stress that can be incorporated into the liner by using an electron beam process; and

FIG. 6 illustrates an exemplary cross-sectional view of an integrated circuit (IC) incorporating devices constructed according to the principles of the present invention.

### DETAILED DESCRIPTION

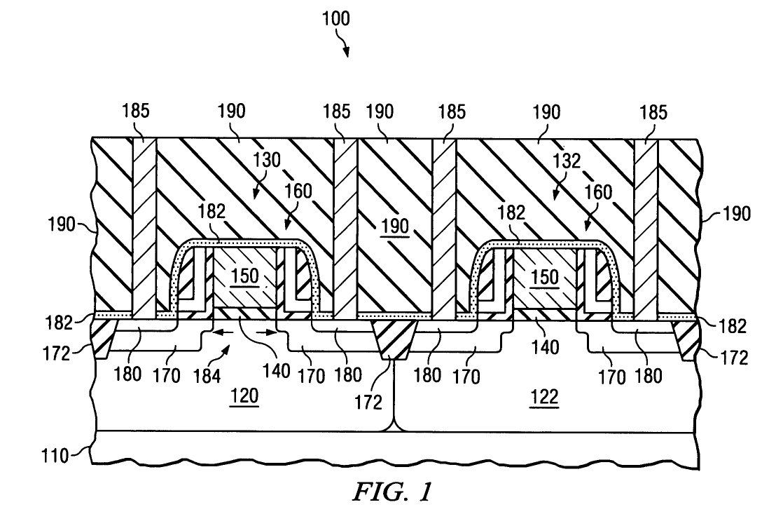

Turning initially to FIG. 1, there is illustrated a partial sectional view of one embodiment of a microelectronics device 100, as provided by the present invention. The microelectronics device 100 includes a conventional semiconductive substrate 110, such as appropriately doped silicon. Other semiconductive materials well known to those skilled in the art may also be used. Located within the substrate 110 in the embodiment of FIG. 1 are complementary doped well regions 120 and 122. Located over the substrate 110 and well regions 120 and 122, respectively, is an NMOS gate structure 130 and a PMOS gate structure 132. In this particular embodiment, the gate structures 130, 132 are complementary NMOS and PMOS devices, with the NMOS device being located over the well region 120 and the PMOS device being located over the well region 122. However, it should be understood that the present invention is not limited to a particular device configuration. For example, in certain embodiments, the gate structures 130, 132 may all be NMOS devices, while in other embodiments, they may all be PMOS devices, or in yet other embodiments, the devices could be bipolar devices.

The gate structures 130, 132 illustrated in FIG. 1 each include a gate oxide 140 located over the substrate 110, as well as a gate electrodes 150 located over the gate oxide 140. The gate electrodes 150 may have a variety of thicknesses, although a thickness ranging from about 50 nm to about 150 nm is advantageous. The gate electrodes 150, when constructed in accordance with the principles of the present invention, may be doped with a number of different materials. For instance, the gate electrodes 150 may be doped with a metal, such as nickel, cobalt, platinum, titanium, tantalum, molybdenum, tungsten, or combinations thereof to form silicided gate electrodes. Further, the respective gate electrodes 150 will be doped appropriately to give optimum performance according to whether it is an NMOS or PMOS device. The presence of one or more of these metals within the gate electrodes 150 provides a gate electrode that does not suffer from depletion as does conventionally doped gate electrodes, and thereby, provides for a more effective microelectronics device. However, after incorporation into the gate electrodes 150, the metals are susceptible to forming piping defects when the thermal process budgets exceed about 400° C. to 450° C. Thus it is highly advantageous to keep the front-end thermal budgets at or below these temperatures after the incorporation of these metals into the device structures.

The gate electrodes 150 may also include a dopant or combination of several types of dopants therein. The dopant, such as boron, phosphorous, arsenic or another similar dopants, based on whether the semiconductor device 100 is operating as a PMOS device or an NMOS device, is configured to tune the minimum energy required to bring an electron from the Fermi level to the vacuum level, or the so called work function.

The gate structures 130, 132 further include conventional gate sidewall spacers 160 flanking both sides of the gate electrodes 150 and gate oxide 140. As seen in the illustrated embodiment, the gate sidewall spacers 160 in the embodiment of FIG. 1 may each include one or more different layers. For instance, the gate sidewall spacers 160 may include a combination of nitride and oxide layers that form a nitride L-shaped sidewall spacer. The gate sidewall spacers 160 may comprise many different types and numbers of layers while staying consistent with the principles of the present invention.

The microelectronics device 100 illustrated in FIG. 1 additionally includes conventional source/drains 170 located within the substrate 110 and proximate the gate oxides 140. The source/drains 170 and are electrically isolated from each other by conventional isolation structures 172, such as trench isolation structures.

Located within the source/drains 170 are silicided source/drain contacts 180. The silicided source/drain contacts 180 in this embodiment comprise silicided nickel. Nonetheless, other metals could be used to form the silicided source/drains 180 and remain within the scope of the present invention. The silicided source/drain contacts 180 may have a depth into the source/drains 170 that ranges from about 10 nm to about 30 nm, among others. Contact plugs 185 are formed in a pre-metal dielectric layer 190 that overlies the gate structures 130, 132 and contact the silicided source/drain contacts 180. The pre-metal dielectric layer 190 is the layer in which the contact plugs 185 are formed and is the dielectric layer on which first metal interconnects are formed.

The microelectronics device 100 also includes a liner 182 that is located over the gate electrodes 150 and the substrate 110. As explained below, the liner 182 that overlies a targeted gate electrode is subjected to an electron beam such that it imparts a stress, indicated by the arrows 184, into the liner, and thus, into the NMOS channel region, which is located between source/drains regions 170. The stress increases electron mobility within the channel region, which in turn, increases the device speed. If the stress is being imparted into the NMOS channel region, the stress is preferably a tensile stress. As explained below, however, the type (tensile versus compressive) and amount of stress imparted can depend on the material from which the liner 182 is made and the duration and intensity of the liner's 182 subjection to the electron beam.

The method of using the electron beam provides advantages over other conventional methods of imparting stress into the channel region in that it can be conducted at much lower temperatures, even to room temperature (e.g. 22° C.). The use of such lower temperatures avoids nickel piping defects within the silicided portions of the microelectronics device 100 that can occur with conventional stress-inducing methods. The electron beam method is also of much shorter duration than other conventional methods, which reduces manufacturing time and thereby increases product output. Moreover, because the electron beam can be tightly controlled, the electron beam can be used without the need of masking the untargeted gate electrodes, which results in a “direct-write” method use of the electron beam. This not only saves times, but it also reduces manufacturing costs.

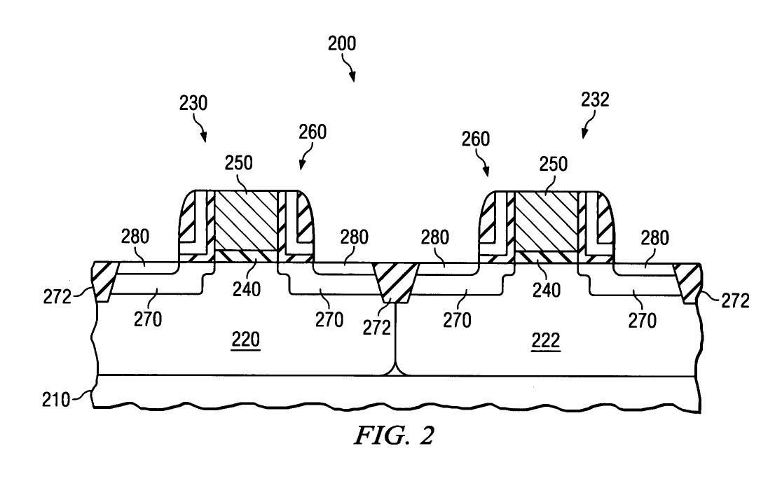

Turning now to FIG. 2, illustrated is a sectional view of a microelectronics device 200 similar to the microelectronics device 100 depicted in FIG. 1 and prior to the formation of the liner 182 mentioned above regarding FIG. 1. FIG. 2 illustrates a partial sectional view of a partially completed microelectronics device 200 manufactured in accordance with the principles of the present invention. The partially completed semiconductor device 200 of FIG. 2 includes a substrate 210. The substrate 210 may, in an exemplary embodiment, be any layer located in the partially completed semiconductor device 200, including a wafer itself or a layer located above the wafer (e.g., epitaxial layer). In the embodiment illustrated in FIG. 2, the substrate 210 is a P-type substrate; however, one skilled in the art understands that the substrate 210 could be an N-type substrate without departing from the scope of the present invention. In such cases, each of the dopant types described throughout the remainder of this document would be reversed. For clarity, no further reference to this opposite scheme will be discussed.

Located within the substrate 210 in the embodiment shown in FIG. 2 are conventionally doped well regions 220, 222. The well region 220, serves as the well for the NMOS device and is doped with a P-type dopant, such as boron while the well region 222 serves as the well for the PMOS device and is doped with an N-type dopant, such as arsenic or phosphorous. Conventional processes and dopant concentrations may be used to form and dope these wells. For example, the well regions 220, 222 could be doped with a dopant dose ranging from about 1E13 atoms/cm² to about 1E14 atoms/cm² and at a energy ranging from about 100 kev to about 500 keV. This results in the well regions 220, 222 having peak dopant concentration ranging from about 5E17 atoms/cm³ to about 1E19 atoms/cm³. However, it should be noted that the dopant concentrations as stated above may vary, depending on the device's application.

Located over the substrate 210 in the embodiment of FIG. 2 are conventionally formed gate structures 230, 232. In the illustrated embodiment, the gate structures 230, 232 each include a gate oxide 240 and a gate electrode 250 that is doped with a metal or other dopants as noted above. The gate oxide 240 may comprise a number of different materials while staying within the scope of the present invention. For example, the gate oxide 240 may comprise silicon dioxide, or in an alternative embodiment comprise a high dielectric constant (K) material. In the embodiment of FIG. 2, however, the gate oxide 240 is a silicon dioxide layer having a thickness ranging from about 0.5 nm to about 5 nm.

While the advantageous embodiment of FIG. 2 dictates that the polysilicon gate electrodes 250 comprise standard polysilicon, other embodiments exist where the polysilicon gate electrodes, or at least a portion thereof, comprise amorphous polysilicon. The amorphous polysilicon embodiment may be particularly useful when a substantially planar upper surface of the polysilicon gate electrodes 250 is desired.

The gate electrodes 250 desirably have a thickness ranging from about 50 nm to about 150 nm, and in one embodiment, the thickness is about 80 nm. Conventional blanket deposition and patterning processes may be used to form the gate electrodes 250 and gate oxides 240.

As mentioned above, the gate electrodes 250 may be doped with one or more metals to form a silicided gate electrode. Conventional deposition processes may be used to locate a metal layer over an exposed surface of the gate electrodes 250. The thickness of the metal layer may vary and will depend, in some embodiments, on the thickness of the gate electrodes 250. For example, in one embodiment where the thicknesses of the gate electrodes 250 are about 80 nm thick, the thickness of the metal layer will be about 60 nm. Preferably, the metal layer is thick enough such that full silicidation of the gate electrodes 250 occurs. However, in other embodiments, full silicidation may not be necessary. In such cases, the metal layer may be thinner. The silicidation can be conducted until the desired work function of the respective gate electrodes 250 is achieved or the gate electrodes 250 are fully silicided.

The deposited metal layer may be nickel or cobalt or a combination thereof. In those embodiments where the metal layer is nickel, an exemplary silicide process comprises placing a blanket of nickel layer over the gate electrodes 250. As it takes approximately 1 nm of nickel to fully silicide approximately 1.8 nm of polysilicon, the thickness of the blanket layer of nickel should be at least 56% of the thickness of the gate electrode 250. To be comfortable, however, it is suggested that the thickness of the layer of nickel should be at least 60% of the thickness of the gate electrode 250. Thus, where the thickness of the gate electrode 250 ranges from about 50 nm to about 150 nm, as described above, the thickness of the blanket layer of nickel should range from approximately 30 nm to about 90 nm. It should also be noted that the blanket layer of metal layer may comprise a number of different metals or combinations of metals, such as nickel and cobalt, while staying within the scope of the present invention.

The nickel layer and the gate electrodes 250 are subjected to a thermal anneal having a temperature ranging from about 400 degrees centigrade to about 600 degrees centigrade and for a period of time ranging from about 10 seconds to about 100 seconds. It should be noted, however, that the silicidation process may vary depending on the amount of silicidation that is desired and the materials that are used to silicide the gate electrodes 250. For example, if the gate electrodes 250 are silicided with a combination of cobalt and nickel, then the silicidation process parameters and percentages of materials used will be different than those just stated above. Those who are skilled in the art will understand how to achieve the desired degree of silicidation when using such metal combinations.

The exemplary embodiment of FIG. 2 further includes conventionally formed sidewall spacers 260. The sidewall spacers may be formed in way that includes an offset spacer that appropriately offsets lightly doped drain (LDD) regions associated with source/drains 270. After the conventional formation of the LDD regions, remaining portions of the sidewalls spacers 260 are formed using conventional deposition and anisotropic etching processes.

Following the patterning of the gate electrodes 250 and gate oxides 240 and formation of the sidewall spacers, the above-mentioned source/drains 270 are conventionally formed adjacent the gate electrodes 250. Generally the source/drain implant involves a high dopant concentration that has a peak dopant concentration ranging from about 1E18 atoms/cm³ to about 1E21 atoms/cm³. Also, the highly doped source/drain implant should typically have a dopant type opposite to that of the well region in which they are located. Following the source/drain implant, a standard source/drain anneal is conducted to activate the source/drains 270. It is believed that a source/drain anneal conducted at a temperature ranging from about 1000° C. to about 1100° C. and a time period ranging from about 1 second to about 5 seconds would be sufficient. It should be noted that other temperatures, times, and processes could be used to activate the source/drains 270, and such processes are known to those skilled in the art. Following the formation of the source/drains 270, silicided contact regions 280 are conventionally formed.

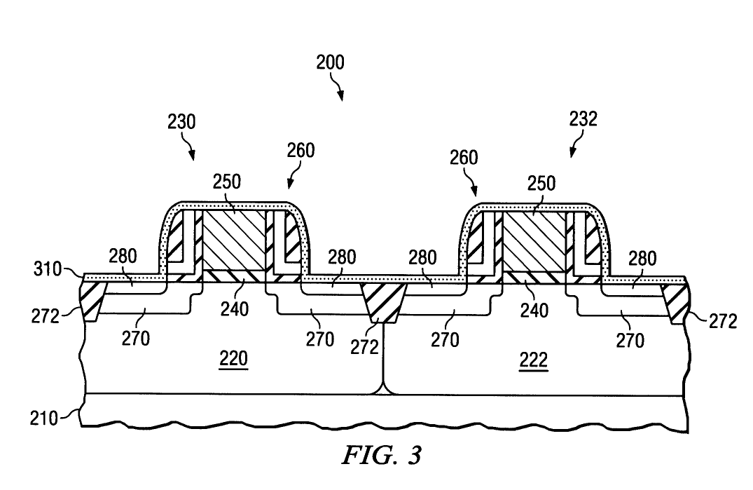

Turning now to FIG. 3 illustrated is a sectional view of the partially completed microelectronics device 200 illustrated in FIG. 2 after the conventional deposition of a liner 310. The liner 310 extends over the substrate 210, NMOS and PMOS gate structures 230 and 232, including the source/drains 270. The thickness of the liner 310 may vary. For example, in one embodiment, the thickness of the liner 310 is less than about 100 nm, with a preferred thickness ranging from about 30 nm to about 100 nm.

The types of materials used to construct the liner 310 may also vary. In one embodiment, the liner 310 may comprise silicon, nitrogen or carbon. Examples of materials that can be used to form the liner 310 include silicon nitride (SiN), silicon carbide (SiC), and silicon oxy-carbide (SiCO). The way in which the liner 310 is formed can control the magnitude and type of stress produced. For example, a compressive stress inducing silicon nitride based liner can be obtained by forming the silicon nitride in a chamber by a plasma enhanced chemical vapor deposition (PEVCD) process with a temperature ranging from about 300° C. to about 450° C., a pressure ranging from about 2.0 to 2.5 torr, a silane flow of about 20 sccm, an ammonia flow of about 500 sccm, a nitrogen gas flow of about 2000 sccm, a high frequency RF power of about 20 watts and a lower frequency RF power of about 50 watts. The deposition temperature, however, should not exceed about 450° C. to avoid the piping defects mentioned above. In conventional processes, these lower deposition temperatures would substantially inhibit the liner's ability to impart the desired amount of stress into the channel region. However, with the present invention, the reduced amount of stress due to deposition temperatures can be compensated for by use of the electron beam curing process.

As another example, a tensile stress inducing silicon nitride based liner can be obtained by forming the silicon nitride with a temperature ranging from about 300° C. to about 450° C., a pressure ranging from about 4.0 torr to about 6.0 torr, a silane flow of about 100 sccm, an ammonia flow of about 3000 sccm, a nitrogen gas flow of about 2000 sccm, a high frequency RF power of about 50 watts and a lower frequency RF power of about 15 watts. In advantageous embodiments, to improve the performance of a PMOS device, a compressive stress is preferred, and to improve the performance of an NMOS device, a tensile stress is preferred. It should be understood that the above examples are provided for illustrative purposes and that the present invention contemplates other formation parameters.

Silicon carbide based liners are generally formed as compressive strain inducing liners. An exemplary nitrogen doped silicon carbide based liner is obtained by forming the liner within a chamber with a temperature of about 350° C., a pressure of about 3.0 torr, a tri-methysilane flow of about 160 sccm, an ammonia flow f about 325 sccm, a helium flow of about 400 sccm, and a RF power of about 300 watts.

The liner 310 shown in FIG. 3 is a blanket deposited layer that extends over both NMOS and PMOS gate structures 130 and 132. However, it should be understood that appropriate masking processes may be employed to place different liner materials over the NMOS and PMOS gate structures 130 and 132 to impart a tensile stress into the channel region of the NMOS gate structure 130 and a compressive stress into the PMOS gate structure 132.

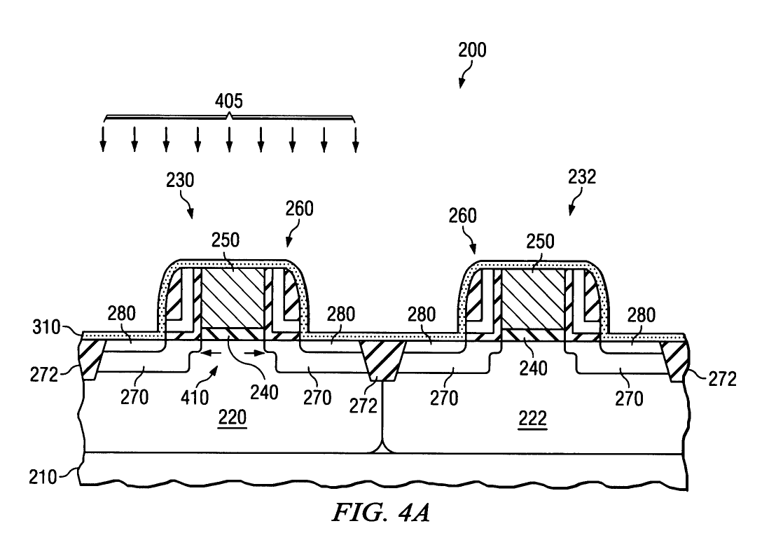

Turning now to FIG. 4A, there is illustrated a partial sectional view of the partially completed microelectronics device 200 illustrated in FIG. 3 during exposure of the liner 310 to an electron beam 405. The electron beam 405 imparts a stress 410 into the channel region of the gate structure. Advantageously, and unlike conventional processes, the electron beam can be highly focused. This allows the process to be directed to a targeted area without the use of a protective mask covering untargeted areas as required by conventional processes. However, the present invention does not preclude the use of a mask and may be used in other embodiments. In the illustrated embodiment, the electron beam 405 is focused on the liner 310 located over the NMOS gate structure 230. Thus only that portion of the liner 310 will be modified to impart more tensile stress into the channel region of the NMOS gate structure 230. Alternatively, the electron beam 405 can be broaden such that it can also expose the liner 310 located over the PMOS gate structure 232 to the electron beam 405 as well. Thus, if different materials overlie the respective NMOS and PMOS gate structures 230 and 232, then additional tensile or compressive stress can be imparted into the channel regions of each of those devices by using the electron beam.

As also mentioned above, the present invention also advantageously provides a method wherein the time required to incorporate a substantial amount of stress is significantly reduced over conventional process. For example, ultra violet light curing process can require from about 10 to 20 minutes to conduct where as the present invention, in one embodiment, provides that the liner 310 is exposed to the electron beam for a period of time ranging from about 30 seconds to about 1 minute.

Turning now to FIG. 4B, following the electron beam process, a conventional pre-metal dielectric layer 415 is deposited over the liner 310 and the gate structures 230, 232. Conventional contacts are formed in the pre-metal dielectric layer 415 to arrive at the structure shown in FIG. 1. Since, these processes are well known, a detailed discussion of them is not necessary. Conventional back-end metallization steps are conducted to construct interconnects to form an operative integrated circuit.

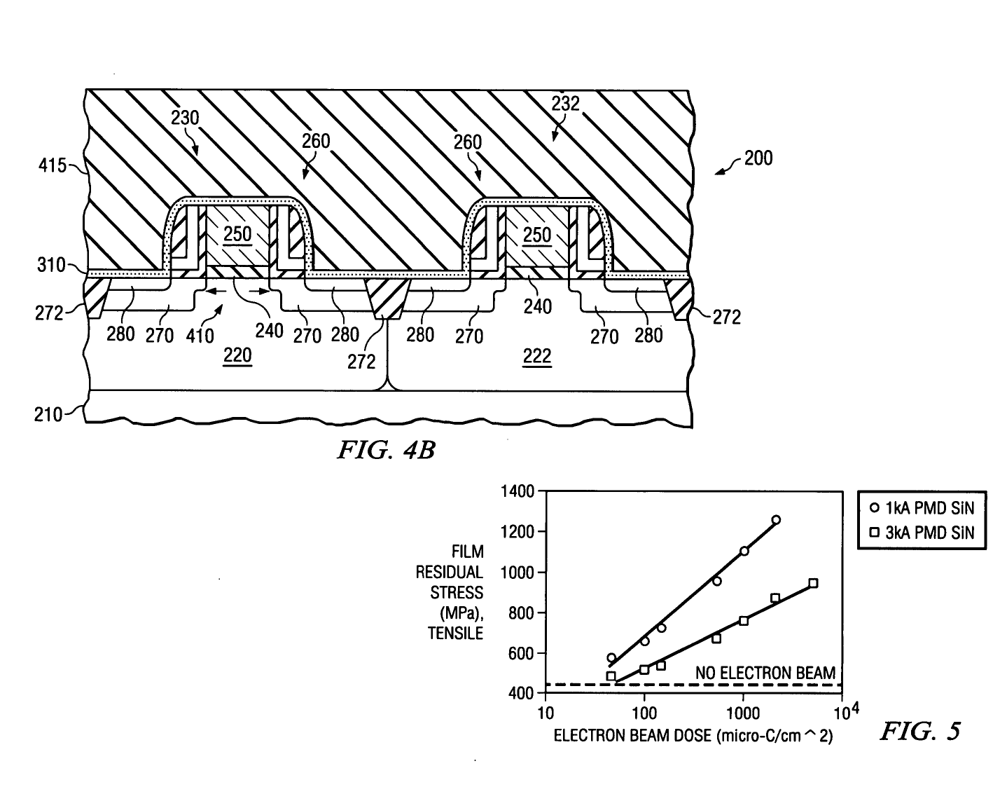

With continued reference to FIGS. 4A and 4B, as seen from FIG. 5, which is a graph of film residual stress versus electron beam dose, the amount of stress can be highly tailored depending on the thickness of the liner 310, the strength of the electron beam, and the time that the liner 310 is exposed to the electron beam. To avoid piping defects in the silicided portions of the microelectronics device 200, the temperature during the exposure of the liner 310 to the electron beam preferably does not exceed about 450° C. and more preferably, the temperature does not exceed about 400° C. Further, the present invention contemplates conducting the electron beam at room temperatures, as noted above. The dose of the electron beam may vary depending on the amount of stress that is intended to be imparted to the liner 310. For example, in one embodiment, the dose of the electron beam 405 may range from about 80 micro-coloumbs/cm² to about 1100 micro-coloumbs/cm². Other operating parameters of the electron beam 405 may also vary. In one advantageous embodiment, the electron beam 405 is conducted at a voltage of about 3 kV, a current of about 3.5 mA and at a pressure of about 0.01 mTorr. Again, it should be understood that these are exemplary parameters and other parameters are well within the scope of the present invention. Similarly, the amount of stress may also vary, which can also be seen from FIG. 5. In one embodiment, the stress that is imparted into the liner 310 by the electron beam may ranges from about 600 MPa to about 1250 MPa.

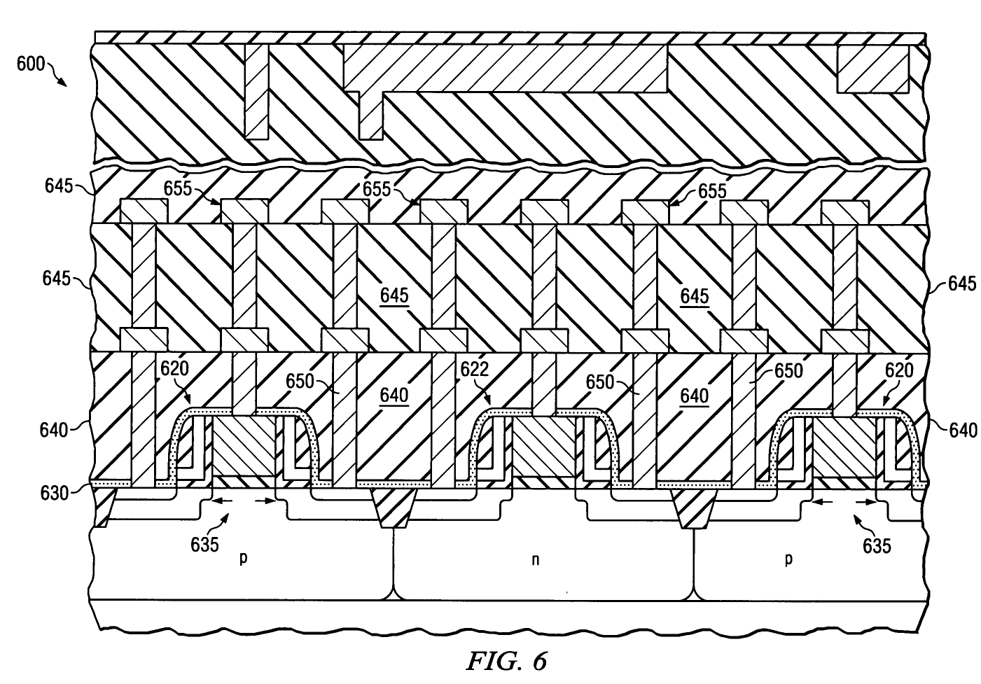

Referring finally to FIG. 6, illustrated is an exemplary cross-sectional view of an integrated circuit (IC) 600 incorporating NMOS and PMOS gate structures 620, 622 as discussed above. The NMOS and PMOS gate structures 620, 622 may include a wide variety of devices, such as transistors used to form CMOS devices, BiCMOS devices, Bipolar devices, as well as capacitors or other types of devices. The IC 600 may further include passive devices, such as inductors or resistors, or it may also include optical devices or optoelectronic devices. Those skilled in the art are familiar with these various types of devices and their manufacture. In the particular embodiment illustrated in FIG. 6, the NMOS gate structure 620 and PMOS gate structure 622 are transistors over which the liner 630 as discussed above is located. The stress 635 that is present within the channel region of the NMOS gate structures 620 is indicated by the arrows. The pre-metal dielectric layer 640 is located over the liner 630 and the NMOS and PMOS gate structures 620, 622 and interlevel dielectric layers 645 are located over the pre-metal dielectric layer 640. The transistors include the various components as discussed above. Additionally, contact plugs 650 are located within the pre-metal dielectric layer and interconnect structures 655 are located within the dielectric layers 645 to interconnect NMOS and PMOS transistors to form the operational integrated circuit 600.

Although the present invention has been described in detail, one who is of ordinary skill in the art should understand that they can make various changes, substitutions, and alterations herein without departing from the scope of the invention.

What is claimed is:

1. A method of fabricating a microelectronic device, comprising:
forming a liner over a substrate and a gate structure;
subjecting the liner to an electron beam; and
depositing a pre-metal dielectric layer over the liner.

2. The method as recited in claim 1, wherein a temperature during the subjecting does not exceed about 400° C.

3. The method as recited in claim 1, wherein the liner comprises silicon, nitrogen or carbon.

4. The method as recited in claim 3, wherein the liner is silicon nitride, silicon carbide nitride, silicon carbide, or silicon oxy-carbide.

5. The method as recited in claim 1, wherein a dose of the electron beam ranges from about 80 micro-coloumbs/cm² to about 1100 micro-coloumbs/cm².

6. The method as recited in claim 5, wherein the electron beam is conducted at a voltage of about 3 kV, a current of about 3.5 mA and at a pressure of about 0.01 mTorr.

7. The method as recited in claim 1 wherein a thickness of the liner is less than about 100 nm.

8. The method as recited in claim 7, wherein a thickness of the liner ranges from about 30 nm to about 100 nm.

9. The method as recited in claim 1, wherein the subjecting forms a stress within the liner that ranges from about 600 MPa to about 1250 MPa.

10. The method as recited in claim 1 wherein the subjecting is conducted for a period of time ranging from about 30 seconds to about 1 minute.

11. A method of fabricating an integrated circuit, comprising:
forming transistors that comprise gate electrodes over a microelectronics substrate;
forming a liner over the microelectronics substrate and the gate electrodes;
subjecting the liner to an electron beam;
depositing a pre-metal dielectric layer over the liner
forming interlevel dielectric layers over the pre-metal dielectric layer; and
forming interconnects in the pre-metal and interlevel dielectric layers to electrically connect the transistors to form an operative integrated circuit.

12. The method as recited in claim 11, wherein a temperature during the subjecting does not exceed about 400° C.

13. The method as recited in claim 11, wherein the liner comprises silicon, nitrogen or carbon.

14. The method as recited in claim 13, wherein the liner is silicon nitride, silicon carbide nitride, silicon carbide, or silicon oxy-carbide.

15. The method as recited in claim 11, wherein a dose of the electron beam ranges from about 80 micro-coloumbs/cm² to about 1100 micro-coloumbs/cm².

16. The method as recited in claim 15, wherein the electron beam is conducted at a voltage of about 3 kV, a current of about 3.5 mA and at a pressure of about 0.01 mTorr.

17. The method as recited in claim 11 wherein a thickness of the liner is less than about 100 nm.

18. The method as recited in claim 11, wherein subjecting the liner to an electron beam includes direct writing an NMOS region of the microelectronics device with an electron beam and without the use of a mask to protect a PMOS region of the microelectronics device.

19. The method as recited in claim 11, wherein the subjecting forms a stress within the liner that ranges from about 600 MPa to about 1250 MPa.

20. The method as recited in claim 11 wherein the subjecting is conducted for a period of time ranging from about 30 seconds to about 1 minute.
